(19) United States
(12) Patent Application Publication
(10) Pub. No.: US 2026/0122822 A1
(43) Pub. Date: Apr. 30, 2026

(54) METHODS AND SYSTEMS FOR ASSEMBLING ELECTRONIC MODULES ONTO SERVER RACKS

(71) Applicant: Super Micro Computer, Inc., San Jose, CA (US)

(72) Inventors: Kuan-Liang LEE, New Taipei City (TW); Cheng-Shi JIANG, New Taipei City (TW); Chia-Yen CHEN, Taoyuan City (TW)

(21) Appl. No.: 18/926,156

(22) Filed: Oct. 24, 2024

(51) Int. Cl. H05K 7/14

(52) U.S. Cl. CPC H05K 7/1487; H05K 7/1489

(57) ABSTRACT

This application is directed to an apparatus configured to couple with a server rack. The apparatus includes a housing configured to be mechanically secured onto a rack structure of the server rack. A release structure is coupled on a front side of the housing. The release structure is configured to receive a user input of an activation force. A spring structure is enclosed in the housing and has a first end fixed a first surface of the housing. The spring structure is configured to extend from the first surface of the housing to unfasten the housing from the rack structure in response to the user input on the release structure, when the housing is mechanically secured to the rack structure.

### TECHNICAL FIELD

This application relates generally to server racks, including, but not limited to, methods, systems, apparatuses, and devices for assembling electronic modules (e.g., a power supply unit) onto a server rack.

### BACKGROUND

A power supply unit (PSU) of a server rack is required to provide power to various electronic devices associated with the server rack. Typically, to allow for maintenance and/or the like, the PSU is removably coupled to the server rack, which allows for servicing the PSU and/or an interior of the server rack. Furthermore, the PSU typically has a relatively small size in comparison to the server rack, particularly an exterior of the PSU that is exposed for an end-user to engage with the PSU. Conventionally, in order to facilitate removal of the PSU from the server rack, the exterior of the PSU is provided with a handle and a latch. The handle and the latch each require a unique figure of the end-user to manipulate, in which a lateral force is applied to the latch in a first direction and a pull force is applied to the handle in a second direction different from the first direction. As such, a relative position of the handle and the latch makes it difficult for the end user to manipulate each with a separate finger.

### SUMMARY

Various embodiments of this application are directed to methods, apparatuses, structures, devices, and systems for automatically unfastening a housing of an electronic module (e.g., a power supply unit), which is originally secured onto a rack structure, from the rack structure. The housing is coupled to a release structure and encloses a spring structure. In response to an activation of the release structure, the spring structure is automatically released, unfastening the housing from the rack structure. The release structure is easy to access, making the release of the electronic module smooth and enhancing user experience with applying a server rack.

In one aspect, some implementations include an apparatus. The apparatus includes a housing configured to be mechanically secured onto a rack structure of the server rack. A release structure is coupled on a front side of the housing. The release structure is configured to receive a user input of an activation force. A spring structure is enclosed in the housing and has a first end fixed a first surface of the housing. The spring structure is configured to extend from the first surface of the housing to mechanically unfasten the housing from the rack structure in response to the user input on the release structure when the housing is mechanically secured to the rack structure.

In another aspect, some implementations include a method of operating the apparatus of the present disclosure. The method includes securing a housing to a rack structure. The method further includes activating the release structure with a user input. Furthermore, the method includes automatically separating the housing from the rack structure via the spring structure in response to the user input.

These illustrative embodiments and implementations are mentioned not to limit or define the disclosure, but to provide examples to aid understanding thereof. Additional embodiments are discussed in the Detailed Description, and further description is provided there.

### BRIEF DESCRIPTION OF THE DRAWINGS

For a better understanding of the various described implementations, reference should be made to the Detailed Description below, in conjunction with the following drawings in which like reference numerals refer to corresponding parts throughout the figures.

FIG. 1 is a front view of an example server rack that supports one or more servers, in accordance with some embodiments.

FIG. 2 is a perspective view of an apparatus having a housing, a release structure, and a spring structure, in accordance with some embodiments.

FIG. 3 is a perspective view of a spring control mechanism applied to unfasten the housing from a rack structure, in accordance with some embodiments.

FIG. 4 is an exploded view of the spring control mechanism shown in FIG. 3, in accordance with some embodiments.

FIG. 5 is a perspective view of a spring structure and a hook structure, in accordance with some embodiments.

FIG. 6A is a front view of a lock mechanism placed in a locked position, in accordance with some embodiments.

FIG. 6B is a front view of a lock mechanism in an unlocked position, in accordance with some embodiments.

FIG. 7 is a side view of an example apparatus (e.g., a PSU) that is pushed into a rack structure, in accordance with some embodiments.

FIG. 8 is an example apparatus that is moved to a locked position in a rack structure, in accordance with some embodiments.

FIG. 9A is an example apparatus locked onto the rack structure, in accordance with some embodiments.

FIG. 9B is an enlarged view of a lock mechanism locked onto a locking structure of a spring structure, in accordance with some embodiments.

FIG. 10A is a side view of a server rack including an apparatus in a locked position, in accordance with some embodiments.

FIG. 10B is a side view of the server rack including the apparatus in an unlocked position, in accordance with some embodiments.

FIG. 11 is a perspective view of an example housing of an apparatus, in accordance with some embodiments.

FIG. 12 is a flow chart of a method for operating an apparatus, in accordance with some embodiments.

Like reference numerals refer to corresponding parts throughout the several views of the drawings.

### DETAILED DESCRIPTION

The present disclosure is directed to providing methods, systems, apparatuses, and devices for coupling an electronic module, such as a power supply unit (PSU) or the like, to a server rack. More particularly, in some embodiments, an apparatus of the present disclosure includes a housing that is configured to be mechanically secured onto a rack structure of the server rack. Moreover, in some embodiments, the housing is configured to support and provide structure to the apparatus. Additionally, the apparatus includes a release structure that is coupled on a front side of the housing. The release structure is configured to receive a user input of an activation force, which allows for manipulating the apparatus via the user input. A spring structure of the apparatus is enclosed in the housing and has a first end fixed a first surface of the housing. The spring structure is configured to extend from the first surface of the housing to mechanically unfasten the housing from the rack structure in response to the user input on the release structure when the housing is mechanically secured to the rack structure. Accordingly, in some situations, when the housing is mechanically secured to the rack structure of the server rack, the spring structure is in an extended state, which allows for a force exerted by the spring structure when returning to an equilibrium, or normal, state, to decouple the apparatus from the rack structure of the server rack.

Reference will now be made in detail to specific embodiments, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used without departing from the scope of claims and the subject matter may be practiced without these specific details.

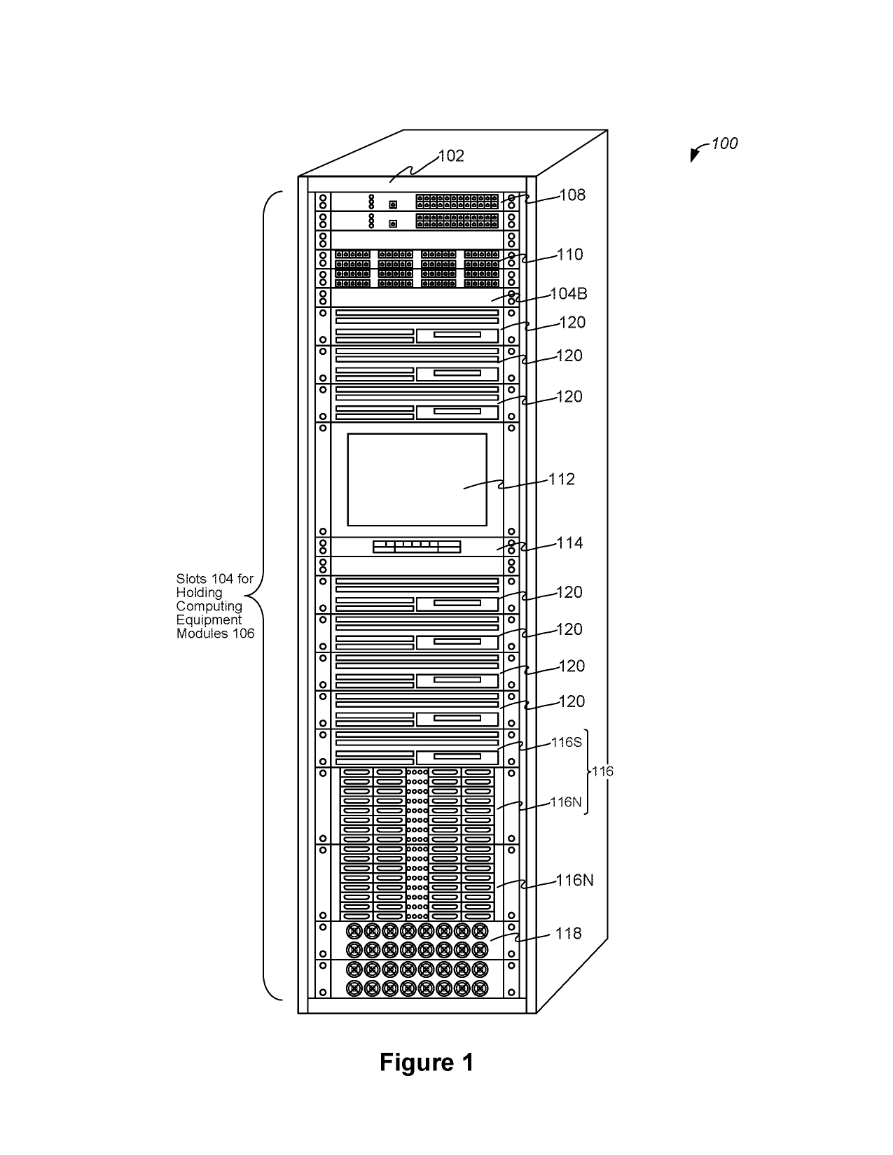

FIG. 1 is a front view of an example server rack 100 (also known as a rack mount, a rack cabinet, or simply a rack) that supports one or more servers 120, in accordance with some embodiments. The server rack 100 includes a frame and a plurality of slots 104, and may be used in a data center, a server room, or a network closet for supporting, organizing, and managing a plurality of computing equipment modules 106 (e.g., servers 120, storage devices 116S and 116N, networking equipment, and other types of hardware). Each of the plurality of slots 104 of the server rack 100 is configured to receive and support a respective computing equipment module 106. In some embodiments, the plurality of slots 104 include at least one blank slot 104B that is not used to provide mechanical support to any equipment module 106 and can receive an equipment module 106 if needed. In some implementations, the server rack 100 has a predefined width of 19 or 23 inches, a height up to 84 inches or more, and a depth selected from 24, 32, 40, or 48 inches.

Examples of the computing equipment modules 106 supported by the plurality of slots 104 of the server rack 100 include, but are not limited to, a firewall module 108, a switch box 110, a server 120, a display device 112, a keyboard 114, a solid-state drive (SSD) 116S, a network-attached storage 116N, and an uninterruptible power supply (UPS) 118. Each computing equipment module 106 plays a respective role in maintaining a network and computing environment. In some embodiments, a firewall module 108 is a network security device that monitors and controls incoming and outgoing network traffic based on predetermined security rules, thereby establishing a barrier between a trusted internal network and untrusted external networks. The firewall module 108 may be placed near a network ingress point to protect the server rack 100 from unauthorized access, malware, and cyberattacks. In some embodiments, the firewall module 108 includes packet filtering, stateful inspection, VPN support, and intrusion prevention systems (IPS). In some embodiments, a switch box 110 is placed near the network ingress point jointly with the firewall module 108, and configured to receive incoming signals and forward the incoming signals (e.g., which may be converted to electrical signals) to different servers 120 mounted on the server rack 100. The switch box 110 is applied in the server rack 100 to minimize cable length and ensure efficient network traffic management. The switch box 110 may support different speeds (e.g., 800 gigabits per second (Gbps), 1.6 Tbs, 3.2 Tbs), have multiple ports (24, 48, etc.), and offer features like virtual local area network (VLAN) support, PoE (Power over Ethernet), and managed or unmanaged capabilities.

The plurality of computing equipment modules 106 of the server rack 100 may include a plurality of servers 120 each of which is configured to provides data, resources, services, or programs to other client devices over one or more wired or wireless communication networks. Each server 120 is mounted in a slot 104 of the server rack 100 and configured to provide one or more services (e.g., web hosting, database management, and application support). The servers 120, mounted on the server rack 100, may provide higher processing power, large memory capacity, redundant power supplies, and hot-swappable components for high availability and reliability compared with individual client devices. In some embodiments, the one or more rack servers 120 include a plurality of graphics processing units (GPU) configured to implement machine learning operations, e.g., in a data center associated with machine learning tasks. In some embodiments, the server 120 includes one or more processors, memory storing one or more programs for execution by the one or more processors, and a system housing for enclosing the one or more processors, the memory, and a power supply component.

The SSD 116S and the network-attached storage 116N are configured to provide storage space for the servers 120 installed in the server rack 100. The SSD uses flash memory to store data and shows high speed, low latency, durability, and lower power consumption, and diverse capacities and form factors compared to hard drive devices (HDDs). Conversely, the network-attached storage (NAS) 116N is a dedicated file storage device that provides data access to a network and allows a large number of different types of client devices to retrieve data from centralized disk capacity. In some embodiments, the network-attached storage 116N may have a high capacity, redundant array of independent disks (RAID), support for a plurality of file-sharing protocols (NFS, SMB/CIFS, FTP), user management, and backup features. In some embodiments, the SSDs 116S are storage drives for speed, and for example, used within the servers 120 disposed on the same server rack 100, while the NAS 116N is configured for file sharing, data backup, and remote access.

In some implementations, the UPS 118 is applied to provide emergency power to other computing equipment modules 106 in case of a power outage, allowing them to remain operational long enough to safely shut down or switch to an alternative power source. In an example, the UPS 118 is mounted in the server rack 100 or placed on a bottom slot to support the weight, providing backup power to other computing equipment modules 106. The UPS 118 provides one or more of battery backup, surge protection, voltage regulation, real-time monitoring, management software, and/or varying runtimes based on capacity and load.

The server rack 100 further includes a plurality of mechanical structures configured to provide mechanical support, or facilitate access, to the plurality of computing equipment modules 106. The plurality of mechanical structures include one or more of: an open frame rack (e.g., having no door or side panel), mounting rails, cable management features (e.g., arms, hooks, and trays), power strips, shelves, drawers, and blanking panels. In some embodiments, the plurality of mechanical structures also includes a rack enclosure (e.g. cabinet), lockable doors, and side panels to protect the computing equipment modules 106 from unauthorized access. In an example, the server rack 100 includes, or is coupled to, a plurality of panels configured to convert the server rack 100 to a server cabinet. In some embodiments, the server rack 100 further includes a cooling system or a ventilation system to facilitate heat dissipation. Using a server rack 100 helps optimize space, improve cooling efficiency, simplify maintenance, and enhance the overall organization and management of information technology (IT) infrastructure.

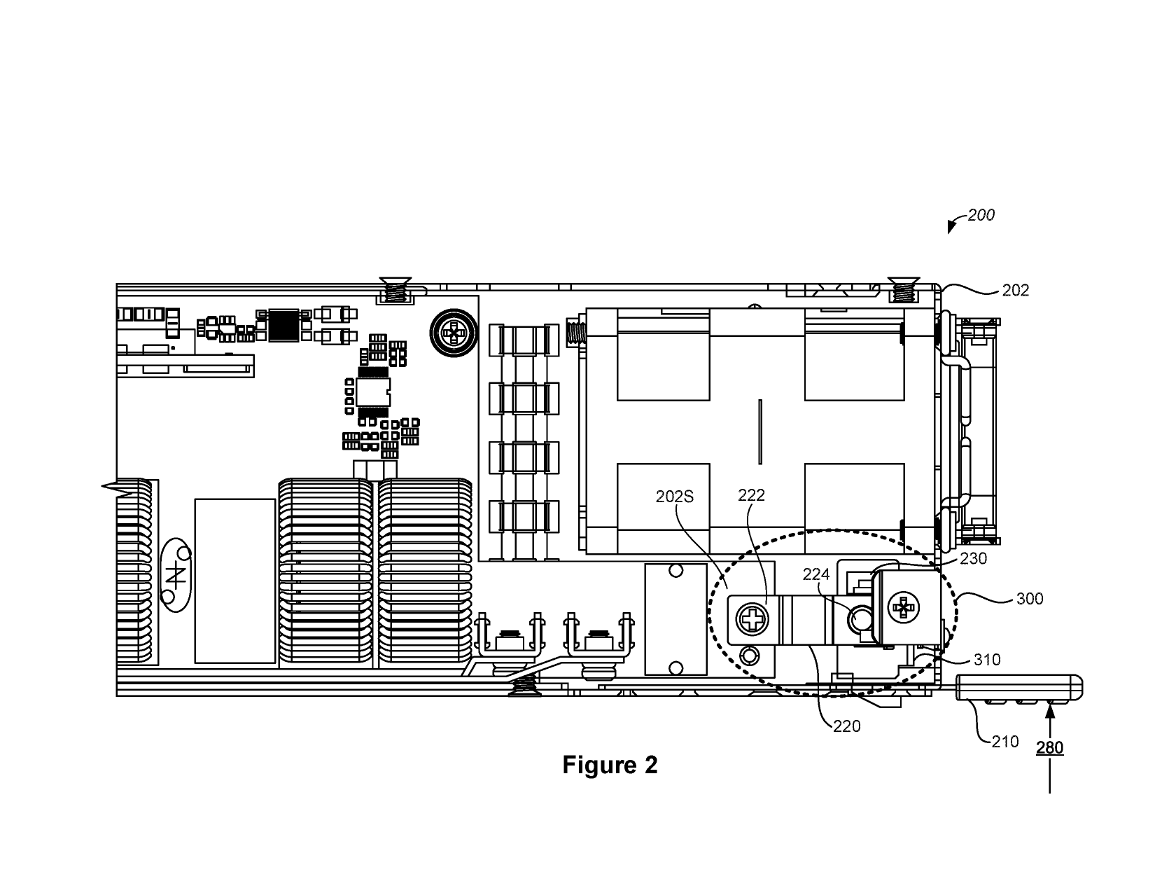

Moreover, in some embodiments, an apparatus 200 (FIG. 2) of the present disclosure is configured to couple with the server rack 100, such as by removably coupling with a surface of the server rack 100 in accordance with a user input provided through the apparatus 200.

FIG. 2 is a perspective view of an apparatus 200 having a housing 202, a release structure 210, and a spring structure 220, in accordance with some embodiments. I

n some embodiments, the apparatus 200 includes the housing 202, which allows, at least in part, for accommodating a portion of the apparatus 200 within an interior of the housing 202. In some embodiments, the housing 202 is a three-dimensional, monolithic structure, which allows for coupling and/or decoupling the entire housing 202 from the server rack 100. However, the present disclosure is not limited thereto. In some embodiments, the apparatus 200 corresponds to a PSU applied by a server 120 (FIG. 1). The housing 202 encloses electronic components associated with the PSU.

In some embodiments, the housing 202 of the apparatus 200 is configured to be mechanically secured onto a rack structure 102 of the server rack 100. For instance, in some embodiments, the housing 202 is fixedly coupled to the rack structure 102 of the server rack 100, such as by using one or more fasteners (e.g., one or more bolts, one or more screws, one or more nails, one or more magnets, one or more cords, etc.) that interface with both a surface of the housing 202 and a surface of the rack structure 102. In some embodiments, the housing 202 of the apparatus 200 is mechanically secured to the rack structure 102 by, at least in part, a friction force between a surface of the housing 202 and a surface of the rack structure 102.

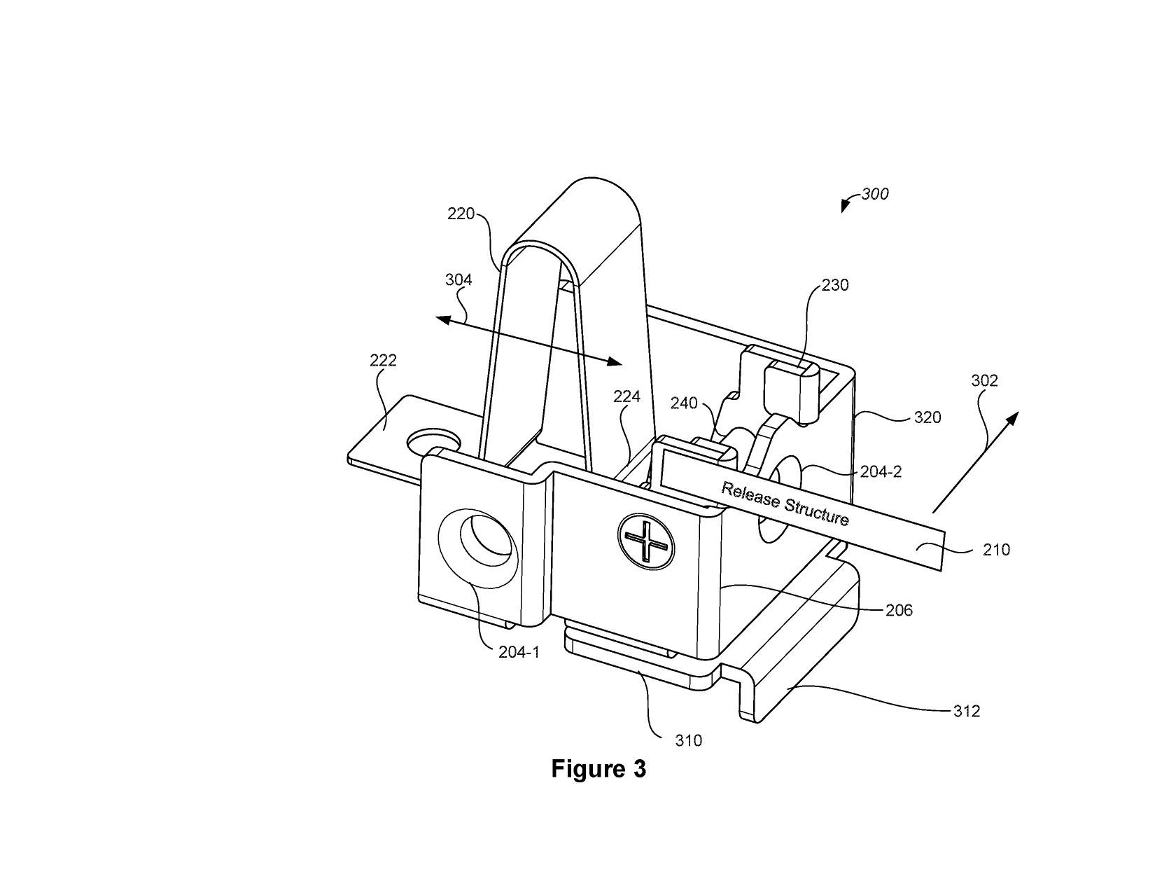

Furthermore, in some embodiments, the apparatus 200 includes a release structure 210, which allows for controlling a portion of the apparatus 200, such as a state of a spring structure 220 of the apparatus 200. Referring to FIG. 3, in some embodiments, the release structure 210 is configured to interface with a portion of the apparatus 200, such as a lock mechanism 230 of the apparatus 200, in order to control a state of the portion of the apparatus 200. In this way, in some such embodiments, the release structure 210 is configured to receive a user input of an activation force, such as a push and/or a pull activation force applied by a finger of the user as input to an end portion of the release structure. Furthermore, in some embodiments, the release structure 210 is coupled on a front side 206 of the housing 202, such as a front end portion of the housing 202. In some embodiments, the release structure 210 is removably coupled to the front side 206 of the housing 202, which allows for selectively using the release structure 210. In some embodiments, the release structure 210 includes a level, a button, a dial, a switch, a toggle, a latch, a pin, or a combination thereof, which allows for controlling a position and/or state of the apparatus 200. However, the present disclosure is not limited thereto.

Furthermore, in some embodiments, the release structure 210 includes a first end portion disposed at an interior portion of the housing 202 and a second end portion disposed at an exterior portion of the housing 202, which allows a user to provide an user input 280 to second end portion of the release structure 210 in order to actuate the first end portion of the release structure 210.

Additionally, the apparatus 200 includes a spring structure 220 that is configured to control a state of the apparatus 200 based on a force associated with the spring structure 220. In some embodiments, the spring structure 220 is enclosed in the housing 202, which allows for applying external forces to the spring structure 220 from an exterior of the housing 202. However, the present disclosure is not limited thereto. For instance, in some embodiments, some or all of the spring structure 220 is disposed in an interior of the housing 202, which protects the spring structure 220, such as from contamination or lateral forces applied to the spring structure 220. However, the present disclosure is not limited thereto.

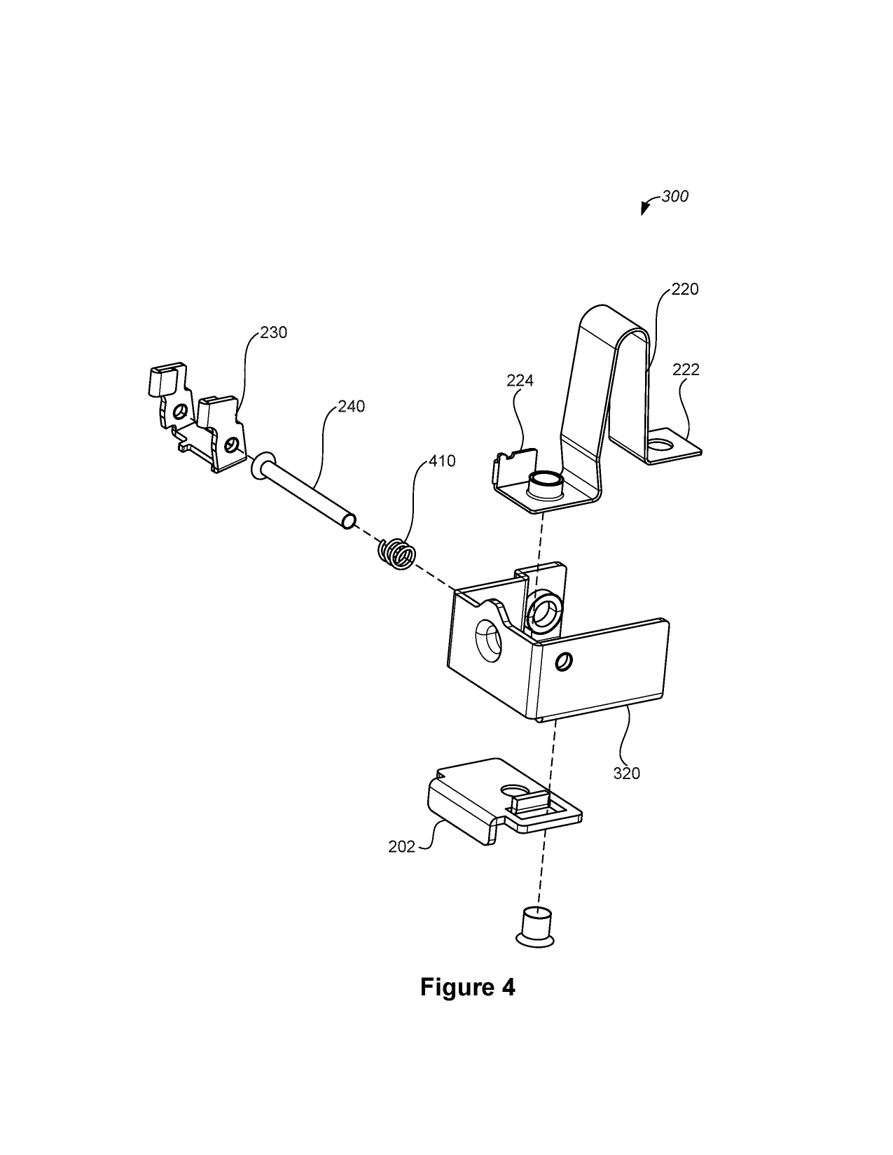

FIG. 3 is a perspective view of a spring control mechanism 300 applied to unfasten the housing 202 from a rack structure 102, in accordance with some embodiments, and FIG. 4 is an exploded view of the spring control mechanism 300 shown in FIG. 3, in accordance with some embodiments.

In some embodiments, the apparatus 200 includes a hook structure 310. In some embodiments, the hook structure 310 includes a surface configured to engage or interface with a corresponding surface, such as a corresponding surface of the rack structure 102, which allows for arresting a position of the apparatus 200 against the corresponding surface. However, the present disclosure is not limited thereto. In some embodiments, the hook structure 310 includes protrusion 312, such as a flange, a collar, a rib, a rim, a rail, and/or the like disposed at an edge portion of the hook structure 310, which allows for the hook structure 310 to be blocked by the rack structure 102. In some embodiments, the protrusion 312 of the hook structure is configured to accommodate and/or receive the corresponding surface of the rack structure 102, which allows for the apparatus to have an aesthetic appearance with the server rack 100.

Furthermore, in some embodiments, the housing 202 has a secure coupling position at which the housing 202 is mechanically secured onto the rack structure 102, which prevents the housing 202 from accidentally decoupling from the rack structure 102. In some such embodiments, a second end 224 of the spring structure 220 includes or is coupled to the hook structure 310, which allows for traversing the hook structure 310 in accordance with a force exerted by the spring structure 220 through the second end 224 of the spring structure 220. In this way, in some such embodiments, the hook structure 310 is configured to be blocked by the rack structure 102, allowing the hook structure 310 to define the secure coupling position of the housing 202.

In some embodiments, the spring structure 220 has a first end 222 that is fixed to a first surface 202S of the housing 202. In some embodiments, the spring structure 220 is configured to extend from the first surface of the housing 202 to mechanically unfasten the housing 202 from the rack structure 102 in response to the user input 280 on the release structure 210 when the housing 202 is mechanically secured to the rack structure 102. Stated another way, when the release structure 210 is activated, the spring structure 220 is automatically stretched to pull and unfasten the housing 202 away from the rack structure 102.

In some embodiments, the housing 202 includes one or more holes 204 (e.g., first hold 204-1, second hold 204-2, etc.) configured to receive a portion of a fastener in the one or more fasteners. However, the present disclosure is not limited thereto.

Referring to FIG. 4,

in some embodiments, the apparatus 200 further includes a lock mechanism 230. In some embodiments, the lock mechanism 230 is coupled to the release structure 210, which allows for controlling the lock mechanism 230 through actuation of the release structure 210, such as a rotation and/or pivot of the release structure. In some embodiments, the lock mechanism 230 is configured to lock the spring structure 220 when the housing 202 is mechanically secured onto the rack structure 102. Furthermore, in some such embodiments, the lock mechanism 230 is further configured to release the spring structure 220 in response to a user input on the release structure 210, such as a first force applied by the user to a first surface of the release structure 210 configured to receive the user input via the first force. However, the present disclosure is not limited thereto.

Furthermore, in some embodiments, the lock mechanism 230 is pivotally coupled on to the rod 240 that is fixedly coupled a bracket structure 320. In some embodiments, the bracket structure 320 is mounted onto a side surface and/or an interior surface of the housing 202.

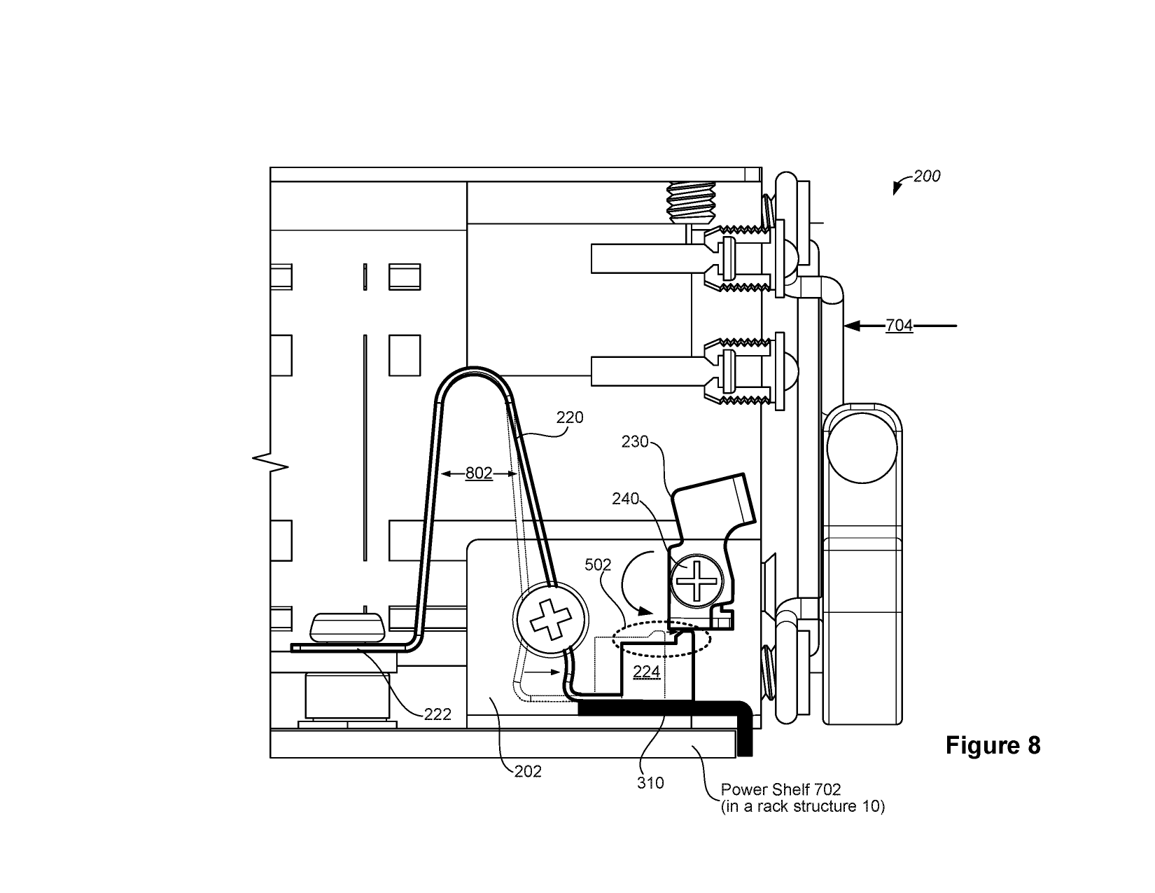

In some embodiments, the activation force 280 is provided along a first direction 302, e.g., perpendicular or substantially perpendicular to a gravitational force. However, the present disclosure is not limited thereto. Moreover, in some embodiments, the spring structure 220 is configured to apply a second force, such as a pull force 802 (FIG. 8), along a second direction 304, to which the first direction 302 is perpendicular or substantially perpendicular. In some embodiments, the first direction 302 and the second direction 304 are perpendicular or substantially perpendicular to one another, and the first direction 302 and the second direction 304 are both perpendicular to the gravitational force. Furthermore, in some such embodiments, the second force is configured for separating the housing 202 from the rack structure 102, such as by traversing the housing 202 from a first position to a second position along the second direction 304. In this way, the force applied by the spring structure 220 allows for removably decoupling (e.g., unfastening) the housing 202 from the rack structure 102 to removing the housing 202 entirely from the server rack 100.

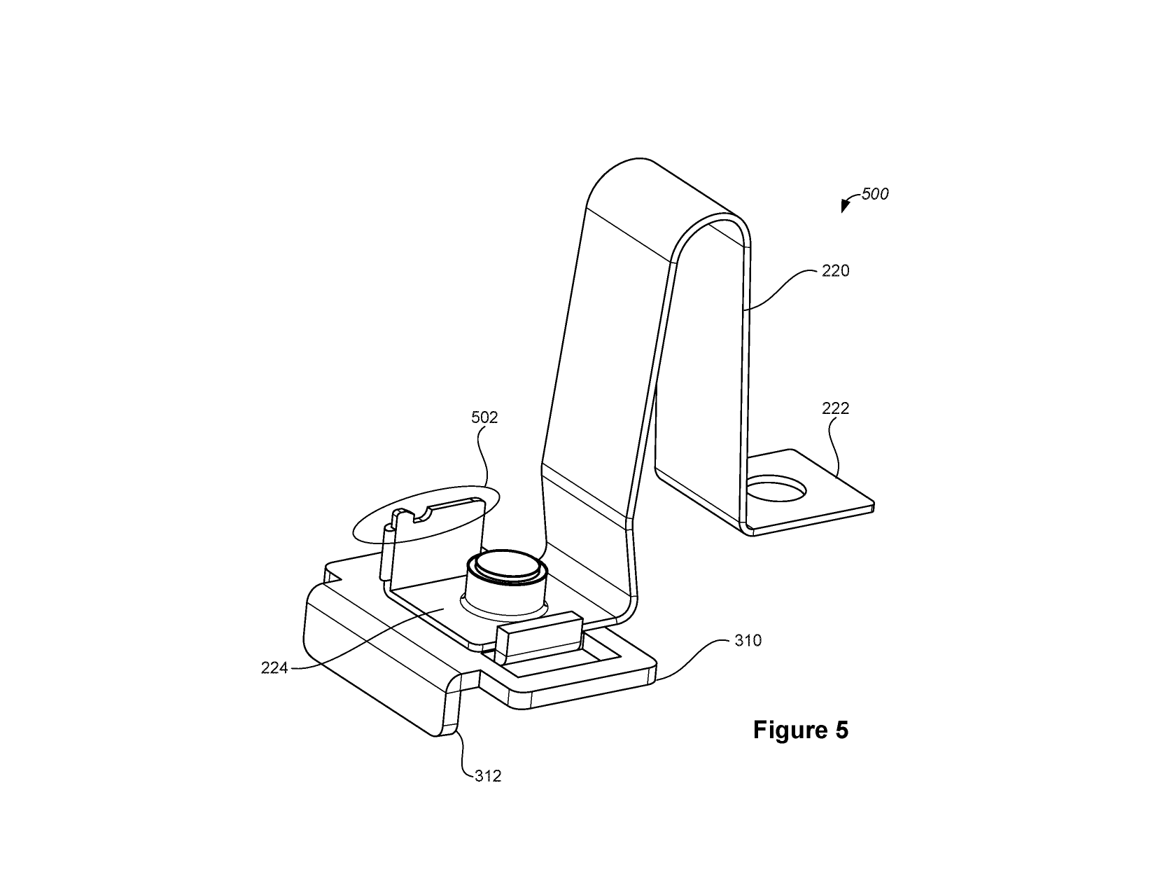

FIG. 5 is a perspective view of a spring structure 220 and a hook structure 310, in accordance with some embodiments. In some embodiments, the spring structure 220 has a second end 224 that is moveable with respect to the housing 202. For instance, in some embodiments, the second end 224 is configured to traverse laterally between a first position (e.g., a locked position) and a second position (e.g., an unlocked position) based on a force applied to the spring structure 220. In some embodiments, the first end 222 of the spring structure 220 is fixedly coupled to the housing 202 and the second end 224 of the spring structure 220 is fixedly coupled to the hook structure 310, which is moveable with respect to the housing 202. Stated another way, the second end 224 of the spring structure 220 is movably coupled to the housing 202, which allows for the second end portion of the spring structure 220 to extend and/or compress from a first position and/or a second position. However, the present disclosure is not limited thereto. The second end 224 of the spring structure 220 is fixedly coupled to the hook structure 310.

In some embodiments, the second end 224 of the spring structure 220 includes a locking structure 502 configured to mate and lock into the lock mechanism 230 coupled to the release structure 210 (e.g., in FIGS. 3 and 4).

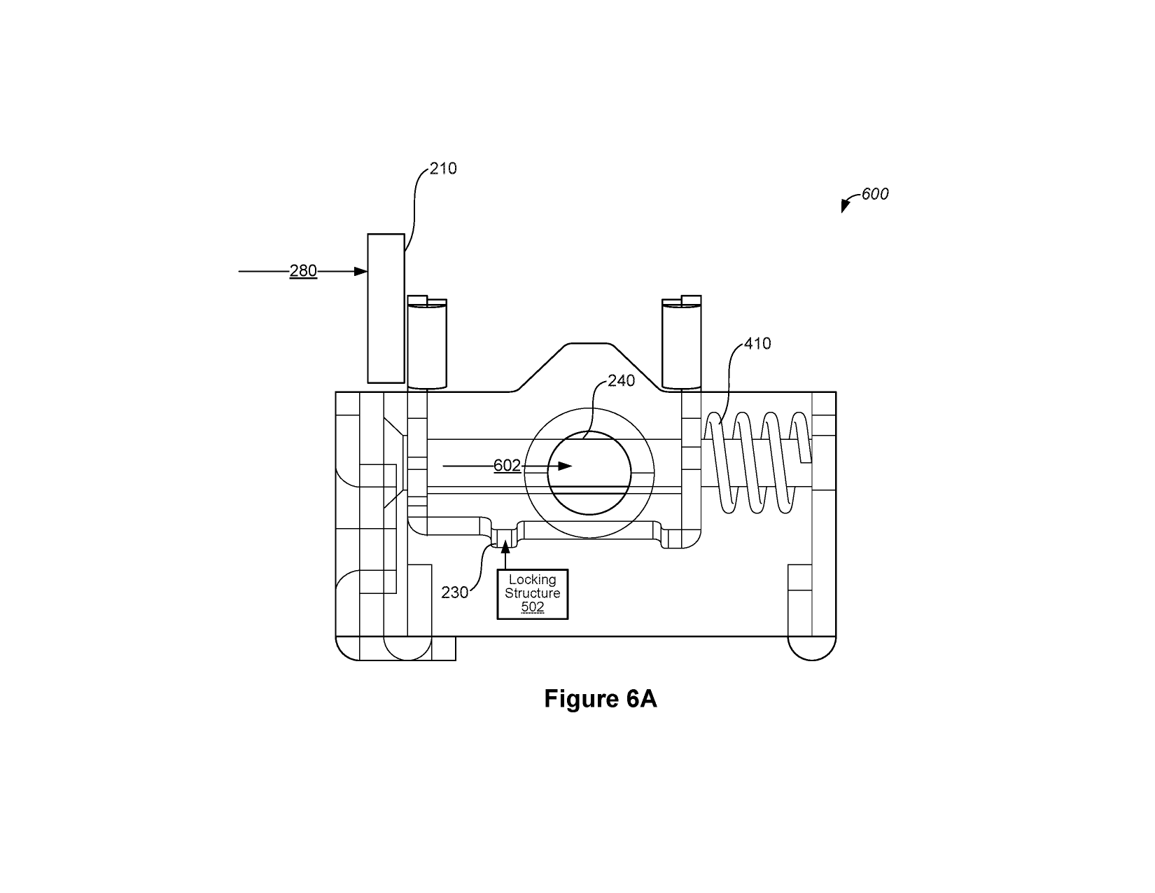

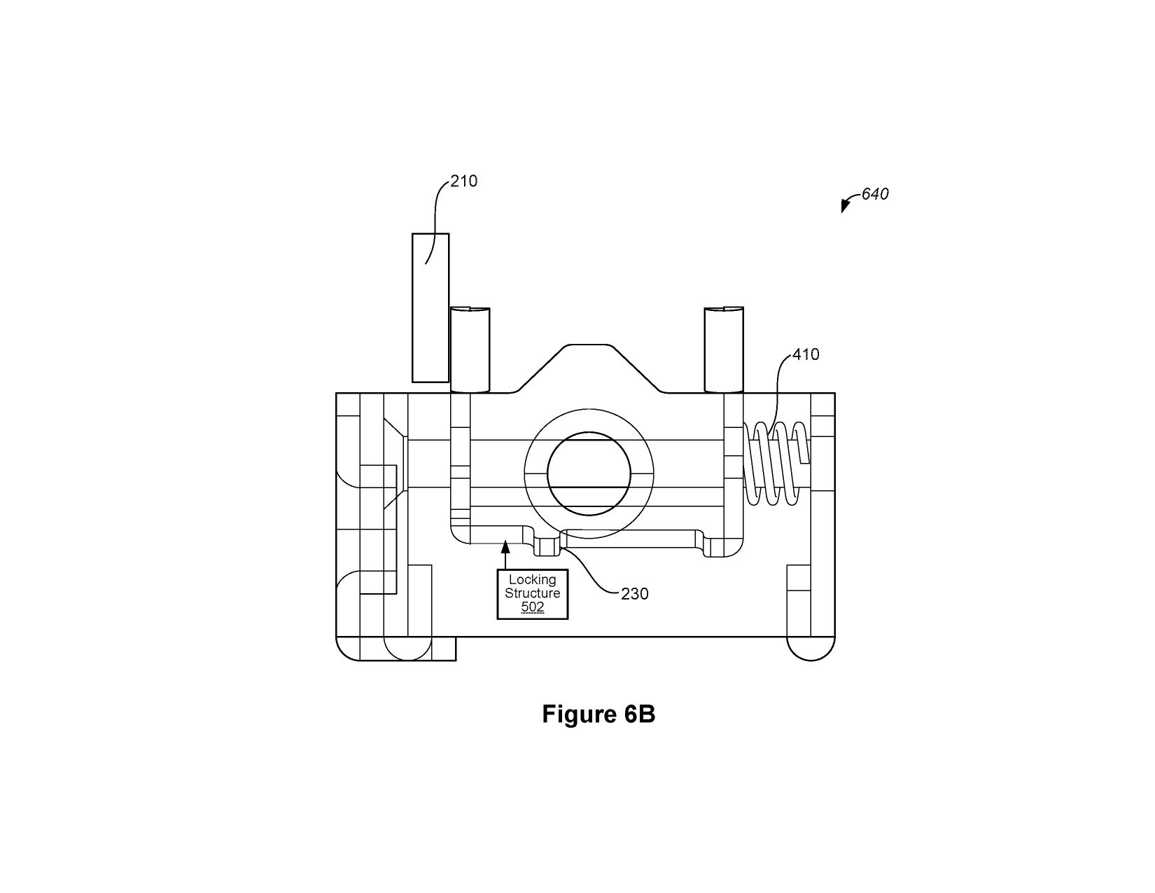

FIG. 6A is a front view of a lock mechanism 230 placed in a locked position 600, in accordance with some embodiments, and FIG. 6B is a front view of a lock mechanism 230 in an unlocked position 640, in accordance with some embodiments. In some embodiments, the lock mechanism 230 is pivotally coupled on to a rod 240, which is provides a rotational degree of freedom for the lock mechanism 230 with respect to an exterior surface of the rod 240 and/or a translational degree of freedom with respect to the exterior surface of the rod 240. For instance, in some embodiments, the rod 240 is configured to fixedly couple onto the housing 202, which allows for the lock mechanism 230 to actuation with respect to the rod 240, and further allows the rod 240 to support the lock mechanism 230. In this way, in some such embodiments, the lock mechanism 230 is configured to slide along, and swing with respect to, the rod 240. In an example, the lock mechanism 230 slides along a direction 602 along the rod 240 and is offset from the locking structure 502, thereby releasing the locking structure 502 and allowing the spring structure 220 to pull its second end 224. For instance, by way of non-limiting example, in FIG. 6A, the lock mechanism 230 is position proximate to a first end portion of the rod 240 and, through movement of the release structure 210, the lock mechanism 230 traverses towards a second end portion of the rod 240 of FIG. 6B. However, the present disclosure is not limited thereto.

Additionally, in some such embodiments, the lock mechanism 230 is mechanically coupled to a locking spring 410 and the release structure 210. In some such embodiments, both the locking spring 410 and the release structure 210 are configured to move the lock mechanism along the rod 240. In some situations, a user input 280 includes an activation force lasting for a shortened duration of time (e.g., 0.5 second). When the user input 280 is applied, the locking spring 410 is compressed. After the user input 280 is removed, the locking spring 510 pushes back the lock mechanism 230 to lock into the locking structure 502 automatically.

In an example, the apparatus 200 includes a PSU used to power a server 120 on a server rack 100. After a user input 280 is applied to push the release structure 210, the lock mechanism 230 is pushed to separate from the locking structure 502 of the spring structure 220 (not shown on FIGS. 6A and 6B). Rebound force of the spring structure 220 automatically unfasten the PSU from the rack structure 102 of the server rack 100.

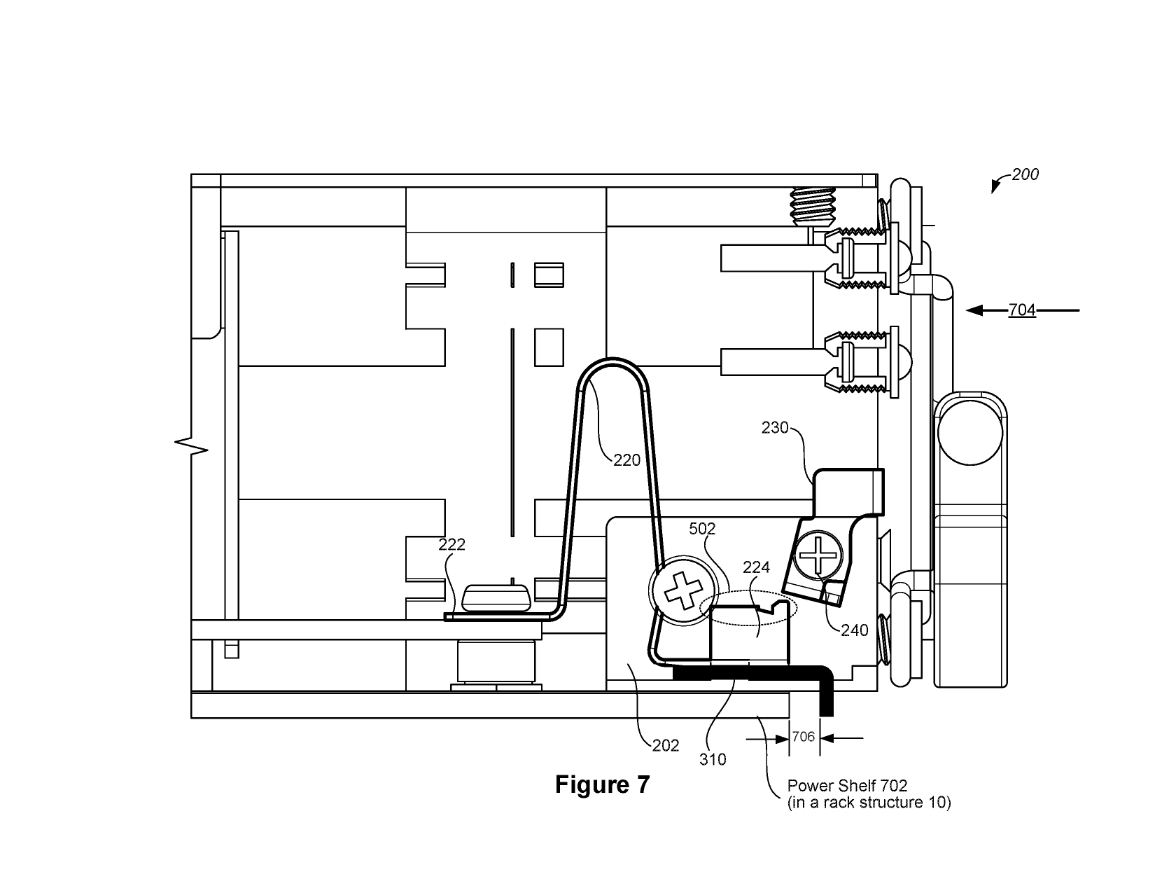

FIG. 7 is a side view of an example apparatus 200 (e.g., a PSU) that is pushed into a rack structure 102, in accordance with some embodiments. The apparatus 200 is placed into an open power shelf 702, and pushed by a force 704 applied on a front surface of the apparatus 200. A bottom surface of the apparatus 200 slides on an interior surface of the power shelf 702 until a rear surface of the apparatus 200 hits a rear surface of the power shelf 702. Referring to FIG. 7, in some situations, the spring structure 220 has an equilibrium, or normal, state. The locking structure 502 of the second end 224 of the spring structure 220 is not locked into the lock mechanism 230 coupled to the release structure 210. A separation 706 exists between a front edge of the power shelf 702 and a tip of the hook structure 310.

In some implementations, the housing 202 further includes an electrical connector exposed on a rear side opposing a front side of the house 202. When the rear surface of the apparatus 200 (i.e., the rear side of the housing 202) hits a rear surface of the power shelf 702, the force 704 continues to be applied to mechanically couple the electrical connector to a rack connector of the rack structure 102, thereby causing the housing 202 to be mechanically secured onto the rack structure 102.

FIG. 8 is an example apparatus 200 that is moved to a locked position in a rack structure 102, in accordance with some embodiments. When the housing 202 of the apparatus 200 is pushed to be mechanically secured onto the rack structure 102, the separation 706 is reduced, e.g., substantially close to zero when the tip of the hook structure 310 is stopped by the front edge of the power shelf 702. As the force 704 continues to be applied before the tip of the hook structure 310 is stopped by the front edge of the power shelf 702, the housing 202 continues to move into the rack structure 102, creating a force 802 to stretch the spring structure 220. The lock mechanism 230 is coupled to the housing 202 by the rod 240 and the bracket structure 320. The lock mechanism 230 is moved with the housing 202, hits a locking structure 502 (FIG. 5) of the spring structure 220, is pivotally rotated with respect to the rod 240.

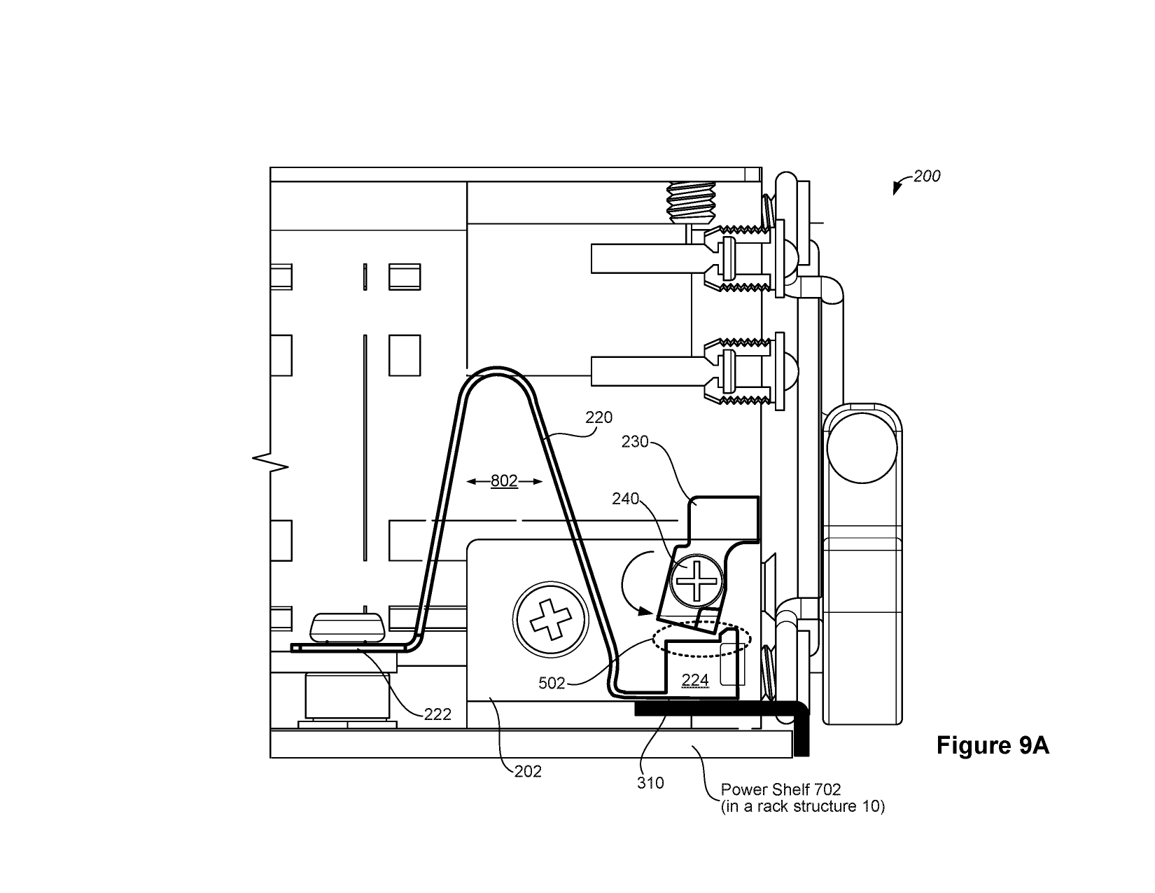

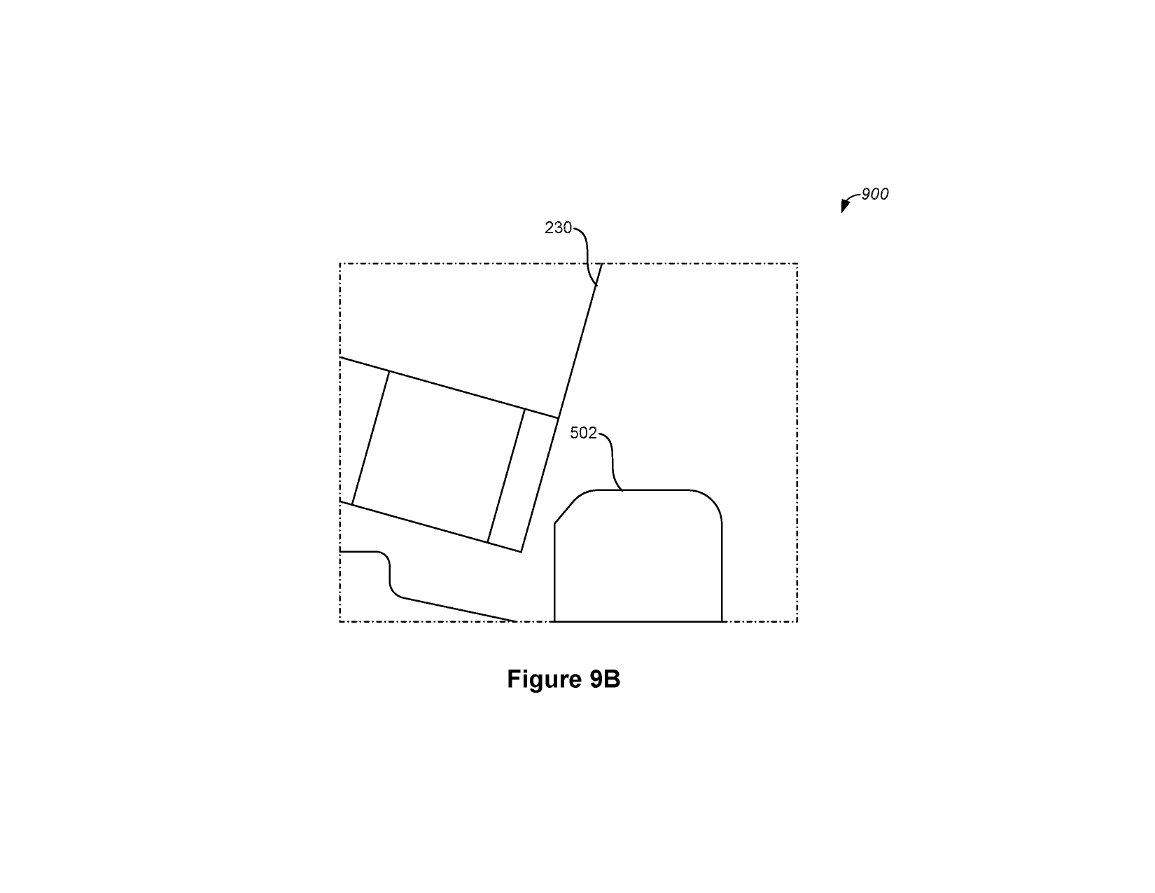

FIG. 9A is an example apparatus 200 locked onto the rack structure 102, in accordance with some embodiments, and FIG. 9B is an enlarged view of a lock mechanism 230 locked onto a locking structure 502 of a spring structure 220, in accordance with some embodiments. The lock mechanism 230 is pushed by the locking structure 502 to pivotally rotate with respect to the rod 240, until the lock mechanism 230 of is locked onto the locking structure 502. For example, in some embodiments, a PSU is pushed into a rack structure 102 to reach a secure position (also called a locked position). In other words, an automatic rebound feature of the spring structure 220 is utilized to allow the locking structure 502 of the spring structure 220 to be locked onto the lock mechanism 230.

In some embodiments, the lock mechanism 230 is configured to be passively controlled by a weight of the lock mechanism 230 and/or a force of the spring structure 220. In some such embodiments, the passive control of the lock mechanism 230 allows for the lock mechanism 230 to swing, pivot, and/or rotate with respect to the rod 240. For instance, in some embodiments, the weight of the lock mechanism 230 causes the lock mechanism 230 to traverse from a first position (e.g., an unlocked position in FIG. 8) to a second position (e.g., a locked position in FIG. 9A), e.g., when a force from the spring structure 220 satisfies a threshold force. However, the present disclosure is not limited thereto.

In some embodiments, the lock mechanism 230 is pushed aside by an activation force 280 to release the locking structure 502 of the spring structure 220. A rebound force of the spring structure 220 automatically pulls the second end 224 of the spring structure 220 to the first end 222, and the hook structure 310 stops the second end 224 from being pulled towards the first end 222 because a tip of the hook structure 310 is blocked by an edge of the power shelf 702. Conversely, the first end 222 of the spring structure 220 is pulled towards the second end 224 and the hook structure 310, thereby unfastening the housing 202 from the rack structure 102. In some embodiments, the housing 202 is mechanically fastened to the rack structure 102, and the rebound force of the spring structure 220 overcomes an associated fastening force. In some embodiments, the housing 202 is placed onto the rack structure 102, relying on a holding force of an electrical connector 1010 and/or a friction force between the housing 202 and the rack structure 102 to stay in position. The rebound force of the spring structure 220 overcomes the holding force of the electrical connector 1010 and/or the friction force between the housing 202 and the rack structure 102.

In some embodiments, the spring structure 220 is configured to apply a first force, such as a pushing for on a surface of the lock mechanism 230 in order to traverse the lock mechanism 230 to a first position (e.g., in FIGS. 6A and 9A), such as a normal position and/or an equilibrium position. In some embodiments (FIG. 9A), the first position is configured to lock the spring structure 220 at a corresponding position. Moreover, in some embodiments, the release structure 210 is configured to provide the activation force 280 (FIG. 6A) to push the lock mechanism 230 away from the normal position.

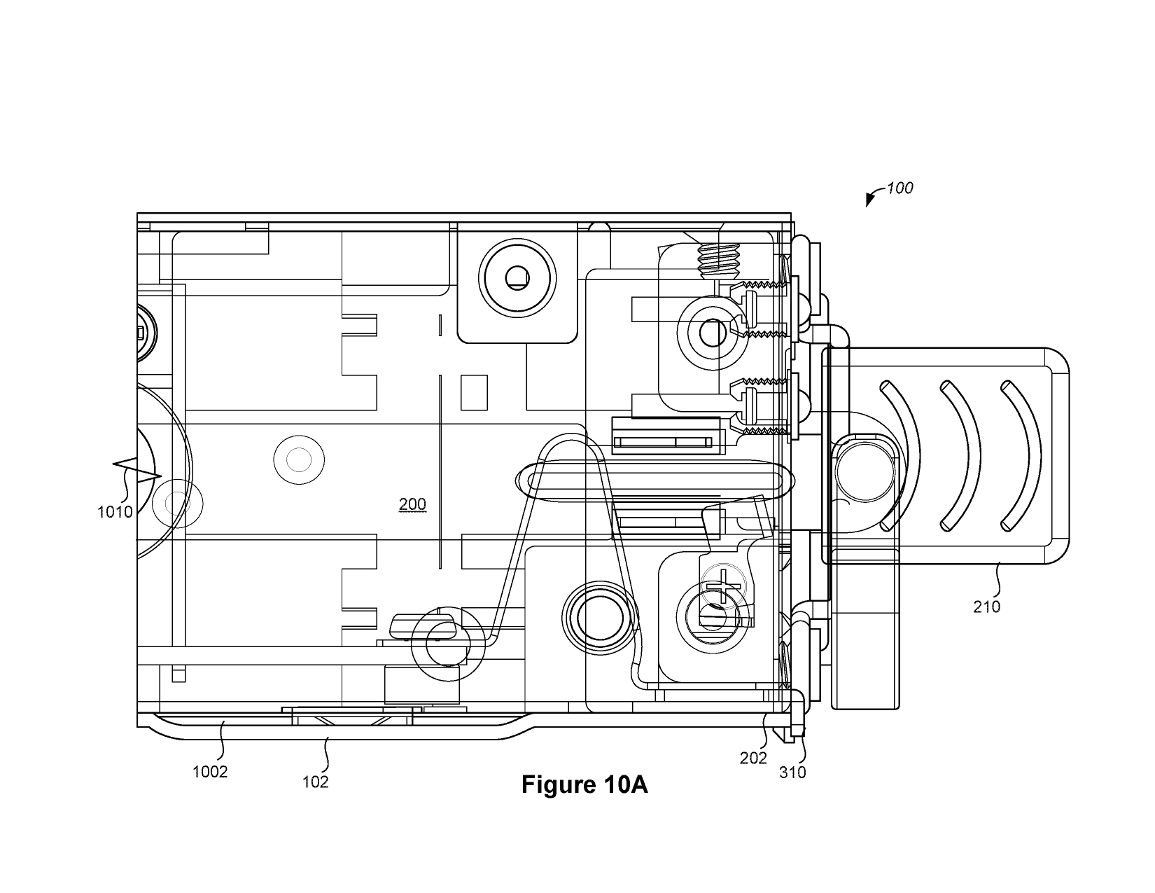

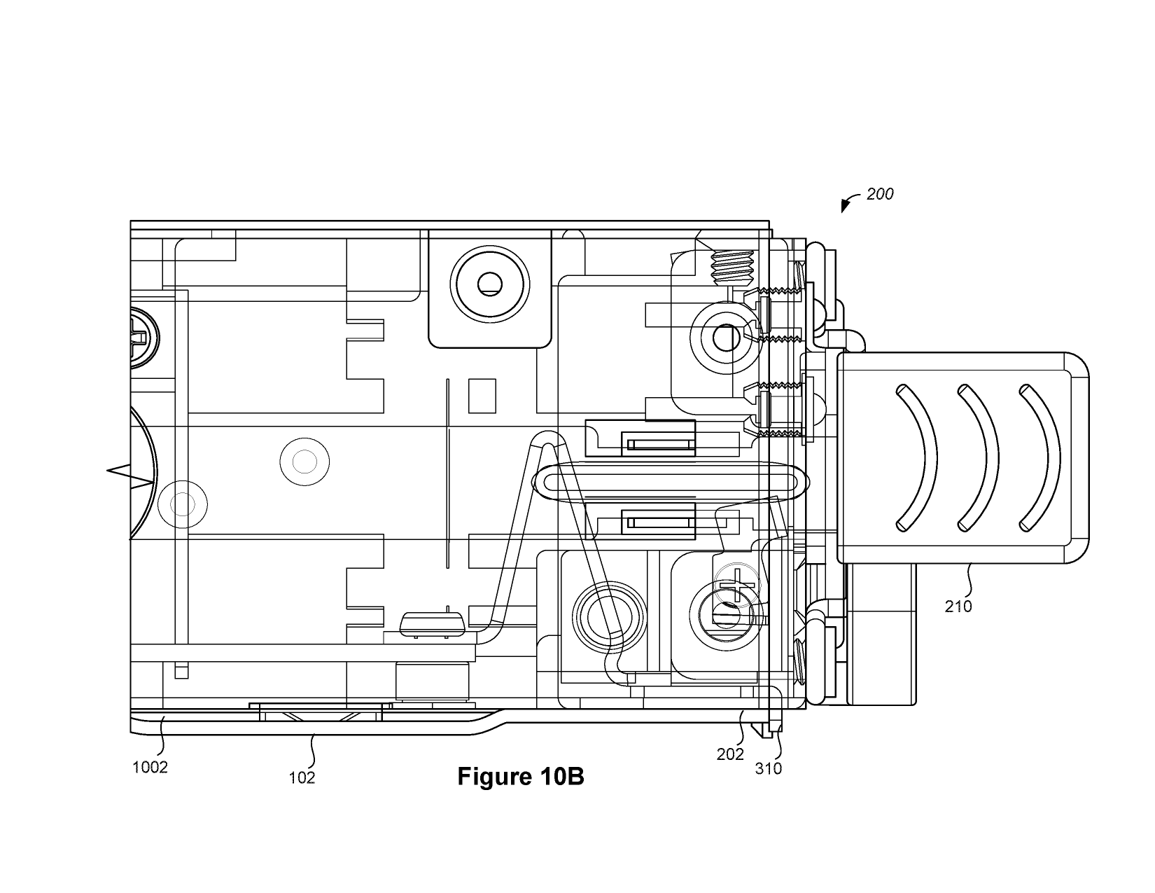

FIG. 10A is a side view of a server rack 100 including an apparatus 200 in a locked position, in accordance with some embodiments, and FIG. 10B is a side view of the server rack 100 including the apparatus 200, in an unlocked position, in accordance with some embodiments.

Referring to FIGS. 10A and 10B, in some embodiments, the housing 202 further includes an electrical connector 1010, which allows for electronic communication between a portion of the apparatus 200 and the server rack 100. For instance, in some embodiments, the electrical connector 1010 is configured to have a portion exposed on or at a rear side of the apparatus 200, which opposes the front side of the apparatus 200. Furthermore, in some such embodiments, the electrical connector 1010 is configured to mate a rack connector of the rack structure 102 when the housing 202 is mechanically secured onto the rack structure 102.

In some embodiments, the housing 202 is configured to accommodate and/or enclose a plurality of electronic components. For instance, in some embodiments, the plurality of electronic components is configured to electrically coupled to the electrical connector of the apparatus 200 and further to the rack structure 102, which allows for electronic communications between the plurality of electronic components and some or all of the rack structure 102 or a portion thereof. Furthermore, in some embodiments, the housing 202 includes one of a server and a power supply unit (PSU), and the rack structure is configured to provide a plurality of servers of a data center. Additionally, in some embodiments, the housing 202 includes the server or the PSU. Furthermore, in some embodiments, the housing 202 includes both the server and the PSU. However, the present disclosure is not limited thereto.

In some embodiments, the housing 202 is configured to resist a detachment force, which prevents the housing 202 from inadvertently and/or accidentally detaching from the rack structure 102. For instance, in some embodiments, the housing 202 is configured to resist a detachment force when the housing 202 is mechanically secured onto the rack structure 102. However, the present disclosure is not limited thereto. In an example, the electrical connector 1010 provides a holding force and contributes to resisting the detachment force. In another example, a friction force between a surface of the housing 202 and the rack structure 102 resist the detachment force applied by the spring structure 220 of the apparatus 200. In some implementations, a shape, a material, and dimensions of the spring structure 220 are configured to provide a pull force greater than the detachment force, which can be resisted by the housing 202. For instance, in some embodiments, the pull force provided by the spring structure 220 is greater than at least a combination of the holding force of the electrical connector 1010 and the friction force between the housing 202 and the rack structure 102.

In some embodiments, the detachment force satisfies a rack connection standard. For instance, in some embodiments, the detachment for is between 0.1 Newtons (N), and 2.5 N, between 0.1 N and 2.2 N, between 0.1 N and 2.0 N, between 0.1 N and 1.7 N, between 0.1 N and 1.3 N, between 0.1 N and 1.1 N, between 0.1 N and 0.7 N, between 0.2 N, and 2.5 N, between 0.2 N and 2.2 N, between 0.2 N and 2.0 N, between 0.2 N and 1.7 N, between 0.2 N and 1.3 N, between 0.2 N and 1.1 N, between 0.2 N and 0.7 N, between 0.5 N, and 2.5 N, between 0.5 N and 2.2 N, between 0.5 N and 2.0 N, between 0.5 N and 1.7 N, between 0.5 N and 1.3 N, between 0.5 N and 1.1 N, between 0.5 N and 0.7 N, between 0.8 N, and 2.5 N, between 0.8 N and 2.2 N, between 0.8 N and 2.0 N, between 0.8 N and 1.7 N, between 0.8 N and 1.3 N, between 0.8 N and 1.1 N, between 1.1 N, and 2.5 N, between 1.1 N and 2.2 N, between 1.1 N and 2.0 N, between 1.1 N and 1.7 N, between 1.1 N and 1.3 N, between 1.5 N, and 2.5 N, between 1.5 N and 2.2 N, between 1.5 N and 2.0 N, between 1.5 N and 1.7 N, between 2.1 N, and 2.5 N, or between 2.1 N and 2.2 N. In some embodiments, the detachment force is at least 0.1 N, at least 0.2 N, at least 0.3 N, at least 0.4 N, at least 0.5 N, at least 0.6 N, at least 0.7 N, at least 0.8 N, at least 0.9 N, at least 1.0 N, at least 1.1 N, at least 1.2 N, at least 1.3 N, at least 1.4 N, at least 1.5 N, at least 1.6 N, at least 1.7 N, at least 1.8 N, at least 1.9 N, at least 2.0 N, at least 2.1 N, at least 2.2 N, at least 2.3 N, at least 2.4 N, or at least 2.5 N. In some embodiments, the detachment force is at most 0.1 N, at most 0.2 N, at most 0.3 N, at most 0.4 N, at most 0.5 N, at most 0.6 N, at most 0.7 N, at most 0.8 N, at most 0.9 N, at most 1.0 N, at most 1.1 N, at most 1.2 N, at most 1.3 N, at most 1.4 N, at most 1.5 N, at most 0.6 N, at most 1.7 N, at most 1.8 N, at most 1.9 N, at most 2.0 N, at most 2.1 N, at most 2.2 N, at most 2.3 N, at most 2.4 N, or at most 2.5 N.

In some embodiments, one or more spring characteristics of the spring structure 220 is configured to provide a pull force, such as a retraction force associated with the spring structure 220, in order to overcome at least the detachment force of the housing 202 in response to the user input on the release structure 210. For instance, in some embodiments, the one or more spring characteristics of the spring structure 220 include an elastic modulus associated with the spring structure 220, a force of the spring structure 220, a stress associated with the spring structure 220, a deflection associated with the spring structure 220, a thickness of the spring structure 220, a width of the spring structure 220, a radius of curvature of the spring structure 220, an interior radius of the spring structure 220, an exterior radius of the spring structure 220, a length of the spring structure 220, two or more lengths of the spring structure 220, or a combination thereof. However, the present disclosure is not limited thereto. For instance, in some embodiments, the one or more spring characteristics of the spring structure include one or more of a material, geometric characteristics, and a spring coefficient. By way of example, in some embodiments, the one or more spring characteristics include a material of the spring structure 220 and/or a portion of two or more dimensions of the spring structure 220, such as a ratio of a first length of the spring structure 220 in comparison to a radius of the spring structure 220. However, the present disclosure is not limited thereto.

In some embodiments, the housing 202 has a bottom side and a protrusion portion 312. In some embodiments, the protrusion portion 312 is configured to hook onto a part of the rack structure 102 and to push the housing 202 out when the spring structure 220 separates the housing 202 from the rack structure 102. Alternatively, in some embodiments, the protrusion portion 312 sits in a recess 1002 of the rack structure 102 and slide within the recess 1002 when the spring structure 220 separates the housing 202 from the rack structure 102. The recess 1002 helps hold the apparatus 200 in the rack structure 102 when the apparatus 200 experiences mechanical disturbances lower than a detachment force tolerance. The rebound force of the spring structure 220 is configured to pull the apparatus 202 out of the recess 10002.

In some embodiments not shown, the release structure 210 includes a plurality of release buttons that are configured to, when activated simultaneously, cause unfastening of the housing from the rack structure.

Now that details regarding an apparatus 200 of the present disclosure have been provided, processes and methods for operating an apparatus 200 of the present disclosure are provided.

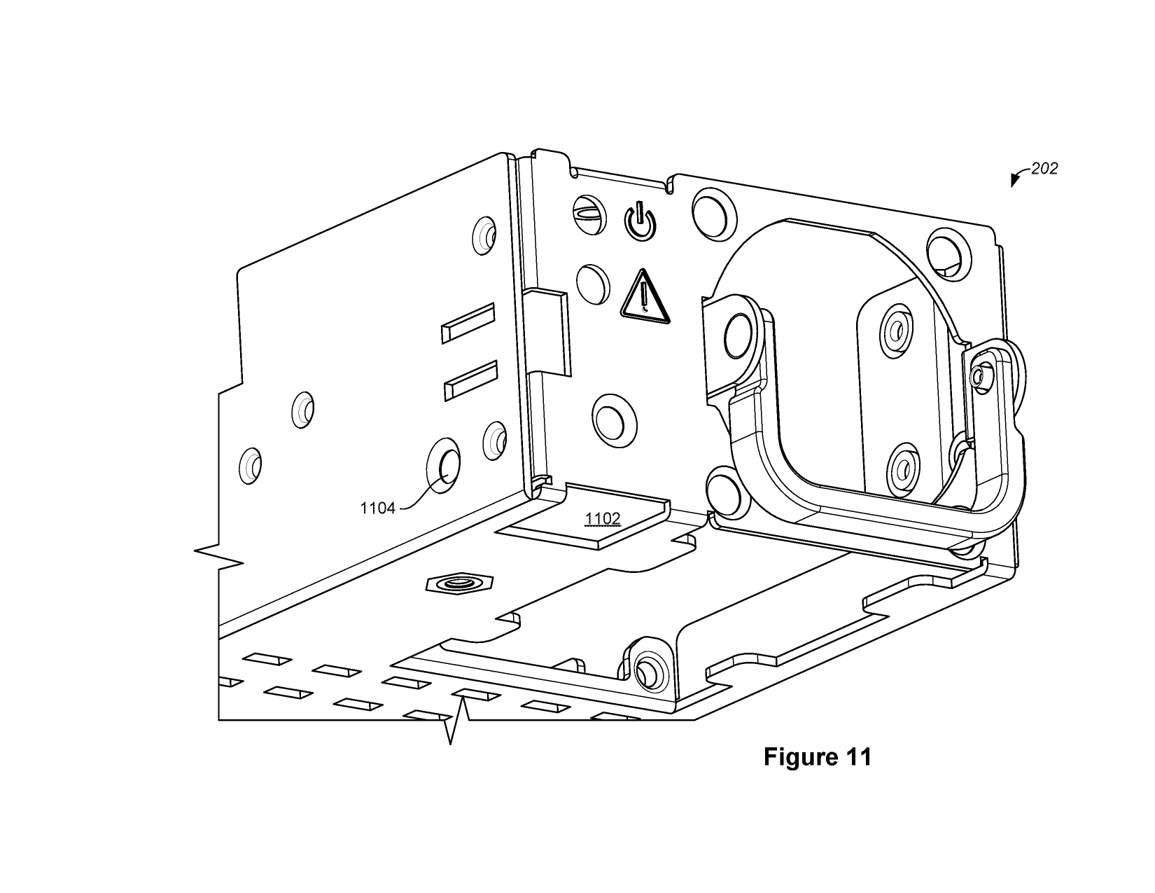

FIG. 11 is a perspective view of an example housing 202 of an apparatus 200, in accordance with some embodiments. The housing 202 includes a first opening 1102 where the hook structure 310 is disposed. The hook structure 310 is fixedly coupled to a second end 224 of the spring structure 220, while a first end 222 is fixed on an interior bottom surface of the housing 202. The hook structure 310 is indirectly coupled to the housing 202 via the spring structure 220, and extends out of the housing 202 to hold onto the rack structure 102. In some embodiments, the housing 202 further includes one or more second holes 1104 via which a bracket structure 320 is coupled to the housing 202. The rod 240, the lock mechanism 230, and the locking spring 410 are coupled onto, and supported by, the bracket structure 320.

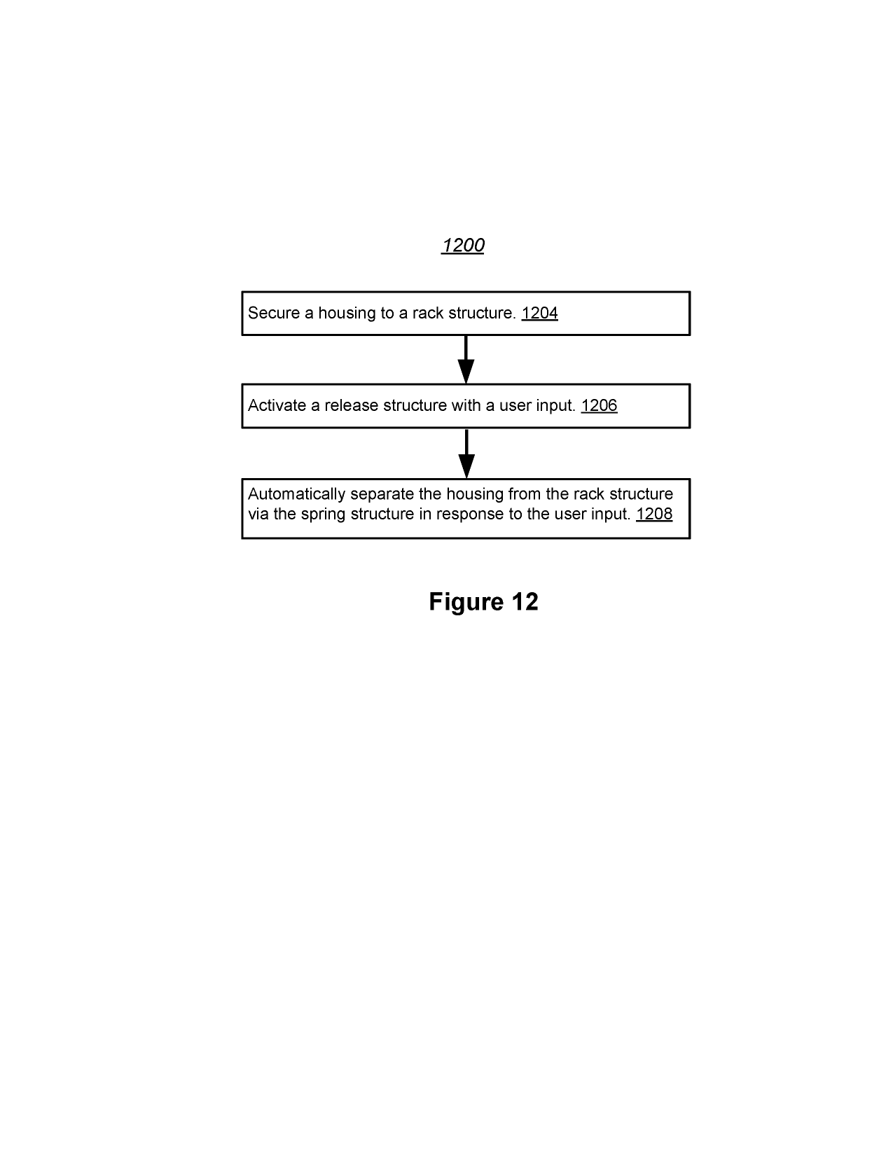

FIG. 12 is a flow chart of a method 1200 for operating an apparatus, in accordance with some embodiments. I

n some embodiments, the present disclosure is directed to providing a method 1200 of operating the apparatus 200 of the present disclosure.

Referring to block 1204, in some embodiments, the method 1200 includes securing a housing 202 to a rack structure.

Referring to block 1206, in some embodiments, the method 1200 includes activating the release structure 210 with a user input.

Referring to block 1208, in some embodiments, the method 1200 includes automatically separating the housing from the rack structure via the spring structure in response to the user input.

Various examples of aspects of the disclosure are described as numbered clauses (1, 2, 3, etc.) for convenience. These are provided as examples, and do not limit the subject technology. Identifications of the figures and reference numbers are provided below merely as examples and for illustrative purposes, and the clauses are not limited by those identifications.

Clause 1. An apparatus, comprising: a housing configured to be mechanically secured onto a rack structure of a server rack; a release structure coupled on a front side of the housing, the release structure configured to receive a user input of an activation force; and a spring structure enclosed in the housing and having a first end fixed a first surface of the housing, wherein the spring structure is configured to, when the housing is mechanically secured to the rack structure, extend from the first surface of the housing to mechanically unfasten the housing from the rack structure in response to the user input on the release structure.

Clause 2. The apparatus of clause 1, further comprising a lock mechanism coupled to the release structure, wherein the lock mechanism configured to lock the spring structure when the housing is mechanically secured onto the rack structure and release the spring structure in response to the user input on the release structure.

Clause 3. The apparatus of clause 2, wherein the lock mechanism is pivotally coupled on to a rod fixed onto the housing, and configured to slide along, and swing with respect to, the rod.

Clause 4. The apparatus of clause 3, wherein the lock mechanism is configured to be passively controlled by its own weight and the spring structure to swing with respect to the rod.

Clause 5. The apparatus of any of clauses 2-4, wherein: the lock mechanism is pivotally coupled on to a rod fixed onto the housing, and mechanically coupled to a locking spring and the release structure; and both the locking spring and the release structure are configured to move the lock mechanism along the road.

Clause 6. The apparatus of clause 5, wherein the spring structure is configured to push the lock mechanism to a normal position configured to lock the spring structure, and the release structure is configured to provide the activation force to push the lock mechanism away from the normal position.

Clause 7. The apparatus of any of clauses 1-6, wherein the activation force is provided along a first direction, and the spring structure is configured to create a pull force along a second direction for separating the housing from the rack structure along the second direction, the first direction being perpendicular to the second direction.

Clause 8. The apparatus of any of clauses 1-7, wherein the housing further includes an electrical connector exposed on a rear side opposing the front side, wherein the electrical connector is configured to mate a rack connector of the rack structure when the housing is mechanically secured onto the rack structure.

Clause 9. The apparatus of clause 8, further comprising: a plurality of electronic components enclosed in the housing, the plurality of electronic components electrically coupled to the electrical connector and further to the rack structure.

Clause 10. The apparatus of any of clauses 1-9, wherein the housing is configured to, when mechanically secured onto the rack structure, resist a detachment force.

Clause 11. The apparatus of clause 10, wherein the detachment force satisfies a rack connection standard.

Clause 12. The apparatus of clause 10 or 11, wherein spring characteristics of the spring structure is configured to provide a pull force to overcome at least the detachment force in response to the user input on the release structure.

Clause 13. The apparatus of clause 12, wherein the spring characteristics of the spring structure include one or more of a material, geometric characteristics, and a spring coefficient.

Clause 14. The apparatus of any of clauses 1-13, wherein the spring structure has a second end that is moveable with respect to the housing.

Clause 15. The apparatus of clause 14, wherein the second end of the spring structure includes a locking structure configured to mate and lock into the release structure.

Clause 16. The apparatus of clause 14 or 15, wherein: the housing has a secure coupling position at which the housing is mechanically secured onto the rack structure; and the second end of the spring structure includes or is coupled to a hook structure, wherein the hook structure is configured to be blocked by the rack structure and define the secure coupling position of the housing.

Clause 17. The apparatus of any of clauses 1-16, wherein the housing includes one of a server and a power supply unit, and the rack structure is configured to provide a plurality of servers of a data center.

Clause 18. The apparatus of any of clauses 1-17, wherein the housing has a bottom side and a protrusion portion, wherein the protrusion portion is configured to sit in a recess of the rack structure and slide within the recess when the spring structure separates the housing from the rack structure.

Clause 19. The apparatus of any of clauses 1-18, wherein the release structure comprises a plurality of release buttons that are configured to, when activated simultaneously, cause unfastening of the housing from the rack structure.

The terminology used in the description of the various described implementations herein is for the purpose of describing particular implementations only and is not intended to be limiting. As used in the description of the various described implementations and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. Additionally, it will be understood that, although the terms “first,” “second,” etc. may be used herein to describe various elements, these elements should not be limited by these terms. These terms are only used to distinguish one element from another.

As used herein, the term “if” is, optionally, construed to mean “when” or “upon” or “in response to determining” or “in response to detecting” or “in accordance with a determination that,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event]” or “in accordance with a determination that [a stated condition or event] is detected,” depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

Although various drawings illustrate a number of logical stages in a particular order, stages that are not order dependent may be reordered and other stages may be combined or broken out. While some reordering or other groupings are specifically mentioned, others will be obvious to those of ordinary skill in the art, so the ordering and groupings presented herein are not an exhaustive list of alternatives. Moreover, it should be recognized that the stages can be implemented in hardware, firmware, software or any combination thereof.

What is claimed is:

1. An apparatus, comprising:
a housing configured to be mechanically secured onto a rack structure of a server rack;
a release structure coupled on a front side of the housing, the release structure configured to receive a user input of an activation force; and
a spring structure enclosed in the housing and having a first end fixed a first surface of the housing, wherein the spring structure is configured to, when the housing is mechanically secured to the rack structure, extend from the first surface of the housing to mechanically unfasten the housing from the rack structure in response to the user input on the release structure.

2. The apparatus of claim 1, further comprising a lock mechanism coupled to the release structure, wherein the lock mechanism configured to lock the spring structure when the housing is mechanically secured onto the rack structure and release the spring structure in response to the user input on the release structure.

3. The apparatus of claim 2, wherein the lock mechanism is pivotally coupled on to a rod fixed onto the housing, and configured to slide along, and swing with respect to, the rod.

4. The apparatus of claim 3, wherein the lock mechanism is configured to be passively controlled by its own weight and the spring structure to swing with respect to the rod.

5. The apparatus of claim 2, wherein:
the lock mechanism is pivotally coupled on to a rod fixed onto the housing, and mechanically coupled to a locking spring and the release structure; and
both the locking spring and the release structure are configured to move the lock mechanism along the rod.

6. The apparatus of claim 5, wherein the spring structure is configured to push the lock mechanism to a normal position configured to lock the spring structure, and the release structure is configured to provide the activation force to push the lock mechanism away from the normal position.

7. The apparatus of claim 1, wherein the activation force is provided along a first direction, and the spring structure is configured to create a pull force along a second direction for separating the housing from the rack structure along the second direction, the first direction being perpendicular to the second direction.

8. The apparatus of claim 1, wherein the housing further includes an electrical connector exposed on a rear side opposing the front side, wherein the electrical connector is configured to mate a rack connector of the rack structure when the housing is mechanically secured onto the rack structure.

9. The apparatus of claim 8, further comprising:
a plurality of electronic components enclosed in the housing, the plurality of electronic components electrically coupled to the electrical connector and further to the rack structure.

10. The apparatus of claim 1, wherein the housing is configured to, when mechanically secured onto the rack structure, resist a detachment force.

11. The apparatus of claim 10, wherein the detachment force satisfies a rack connection standard.

12. The apparatus of claim 10, wherein spring characteristics of the spring structure is configured to provide a pull force to overcome at least the detachment force in response to the user input on the release structure.

13. The apparatus of claim 12, wherein the spring characteristics of the spring structure include one or more of a material, geometric characteristics, and a spring coefficient.

14. The apparatus of claim 1, wherein the spring structure has a second end that is moveable with respect to the housing.

15. The apparatus of claim 14, wherein the second end of the spring structure includes a locking structure configured to mate and lock into the release structure.

16. The apparatus of claim 14, wherein:
the housing has a secure coupling position at which the housing is mechanically secured onto the rack structure; and
the second end of the spring structure includes or is coupled to a hook structure, wherein the hook structure is configured to be blocked by the rack structure and define the secure coupling position of the housing.

17. The apparatus of claim 1, wherein the housing includes one of a server and a power supply unit, and the rack structure is configured to provide a plurality of servers of a data center.

18. The apparatus of claim 1, wherein the housing has a bottom side and a protrusion portion, wherein the protrusion portion is configured to sit in a recess of the rack structure and slide within the recess when the spring structure separates the housing from the rack structure.

19. The apparatus of claim 1, wherein the release structure comprises a plurality of release buttons that are configured to, when activated simultaneously, cause unfastening of the housing from the rack structure.

20. A method of operating an apparatus, comprising:
securing a housing to a rack structure;
activating the release structure with a user input; and
automatically separating the housing from the rack structure via the spring structure in response to the user input.
